(19) United States
(12) Patent Application Publication
(10) Pub. No.: US 2002/0149984 A1
(43) Pub. Date: Oct. 17, 2002

(54) Semiconductor physical quantity sensing device

(76) Inventors: Mutsuo Nishikawa, Nagano (JP); Katsumichi Ueyanagi, Nagano (JP); Katsuyuki Uematsu, Nagano (JP); Osamu Morita, Kanagawa (JP)

Correspondence Address: STAAS & HALSEY LLP, 700 11TH STREET, NW, SUITE 500, WASHINGTON, DC, 20001, US

(21) Appl. No.: 10/120,778

(22) Filed: Apr. 12, 2002

(30) Foreign Application Priority Data
Apr. 12, 2001 (JP) 2001-114332

(51) Int. Cl. G11C 7/02

(52) U.S. Cl. 365/207

(57) ABSTRACT

A semiconductor physical quantity sensing device to perform electrical trimming at low cost by using a CMOS manufacturing process and a small number of terminals. The semiconductor physical quantity sensing device includes a wheatstone bridge circuit, which is a sensor element, an auxiliary memory circuit, which stores provisional trimming data, a main memory circuit, which stores finalized trimming data, an adjusting circuit, which adjusts the output characteristics of the sensor element based on trimming data stored in the auxiliary memory circuit or the main memory circuit, with the elements and circuits being only configured of active elements and passive elements manufactured by way of the CMOS manufacturing process formed on a same semiconductor chip together with seven or eight terminals.

### CROSS-REFERENCE TO RELATED APPLICATIONS

This application claims the benefit of Japanese application no. 2001-114332, filed Apr. 12, 2001, the disclosure of which is incorporated herein by reference.

### BACKGROUND OF THE INVENTION

1. Field of the Invention

The present invention relates to semiconductor physical quantity sensing devices such as pressure sensors, acceleration sensors, and the like used in various kinds of apparatuses for automotive use, medical use, industrial use, etc., and more particularly to semiconductor physical quantity sensing devices having a configuration which performs sensitivity adjustment, adjustment of temperature characteristics, offset adjustment, etc., by way of electric trimming using an EPROM.

2. Description of the Related Art

Recently, electric trimming methods and apparatuses for adjusting the output characteristics of physical quantity sensors enable adjustment after an assembly process, because conventional laser trimming methods have the disadvantage of not permitting re-adjustment even when a variation in output characteristics occurs during the assembly process following trimming. However, electric trimming results in increased manufacturing costs caused by an increase in the number of wire bonding points, due to the need for numerous control terminals for inputting/outputting trimming data, writing data into the EPROM, etc. In order to solve this problem, proposals have been made to perform electric trimming with a small number of terminals by creating a plurality of terminal operation threshold voltages by using resistive potential division and bipolar transistors. (For example Japanese Patent Application Laid-open No. Hei6-29555.)

However, since the above-mentioned proposal uses bipolar transistors, with a mixing of EPROM(s) made by the CMOS process with bipolar transistors, the BiCMOS process becomes necessary, which has the disadvantage of inviting cost increases. To solve this problem, the use of MOS transistors, in place of the bipolar transistors in the above-mentioned proposal, has been considered. However, in such a case, the upper limit of the threshold voltages that can be set with MOS transistors is lower than with bipolar transistors, so the spacing between the plurality of thresholds becomes smaller and there is the disadvantage that mis-operation is more likely to occur. To prevent such problems, it is necessary to increase the upper limit of the threshold voltages to a level equal to that of bipolar transistors but to do that, it is necessary to make MOS transistors capable of higher voltage tolerances and to add new protection circuits, which has the problem of inviting further cost increases.

### SUMMARY OF THE INVENTION

With the foregoing in view, it is an object of the present invention to provide a semiconductor physical quantity sensing device capable of electric trimming which can be manufactured by a CMOS manufacturing process, which is low in cost, and only includes a small number of terminals.

To achieve the above-mentioned objective, the semiconductor physical quantity sensing device of the present invention includes a sensing element, an auxiliary memory circuit such as a shift register that stores provisional trimming data, a main memory circuit such as an EPROM that stores the finalized trimming data, and an adjusting circuit that adjusts the output characteristics of the sensor element based on trimming data stored in the auxiliary memory circuit or the main memory circuit. These elements and circuits are formed on the same semiconductor chip and are configured only of active elements and passive elements which can be manufactured by the CMOS manufacturing process. In addition, the semiconductor physical quantity sensing device has an output terminal, a trimming data input terminal, a terminal for providing a ground potential, a terminal for providing operating voltage, a terminal for inputting an external clock, a terminal for inputting a control signal for the internal digital circuit(s), and one or two terminals for providing voltages for writing data into the main memory circuit, for a total of seven or eight terminals.

According to the present invention, by measuring the sensor output while gradually changing provisional trimming data stored in the auxiliary memory circuit, and trimming data, which results in the desired sensor output, can be determined and stored in the main memory circuit. In the normal operating state, the sensor output may be adjusted by the adjusting circuit using trimming data stored in the main memory circuit. These elements, the auxiliary memory circuit, main memory circuit, and adjusting circuit are configured only of active elements and passive elements manufactured by means of the CMOS manufacturing process and, together with the seven or eight terminals, are formed on the same semiconductor chip.

### BRIEF DESCRIPTION OF THE DRAWINGS

These and other objects and advantages of the present invention will become apparent and more readily appreciated from the following description of the embodiments, taken in conjunction with the accompanying drawings of which:

FIG. 1 is a block diagram illustrating a semiconductor physical quantity sensing device according an embodiment of the present invention;

FIG. 2 is a block diagram illustrating a semiconductor pressure-sensing device formed on a semiconductor chip according to an embodiment of the present invention;

FIG. 3 is a diagram illustrating an example of a shift register configuration in a semiconductor pressure-sensing device of the embodiment of the present invention shown in FIG. 2;

FIG. 4 is a table illustrating operating modes of a semiconductor pressure-sensing device of the embodiment of the present invention shown in FIG. 2;

FIG. 5 is a timing chart illustrating an operational timing of a semiconductor pressure-sensing device of the embodiment of the present invention shown in FIG. 2;

FIG. 6 is a timing chart illustrating an operational timing of a semiconductor pressure-sensing device of the embodiment of the present invention shown in FIG. 2;

FIG. 7 is a timing chart illustrating an operational timing of a semiconductor pressure-sensing device of the embodiment of the present invention shown in FIG. 2; and

FIG. 8 is a timing chart illustrating an operational timing of a semiconductor pressure-sensing device of the embodiment of the present invention shown in FIG. 2.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below in order to explain the present invention by referring to the figures.

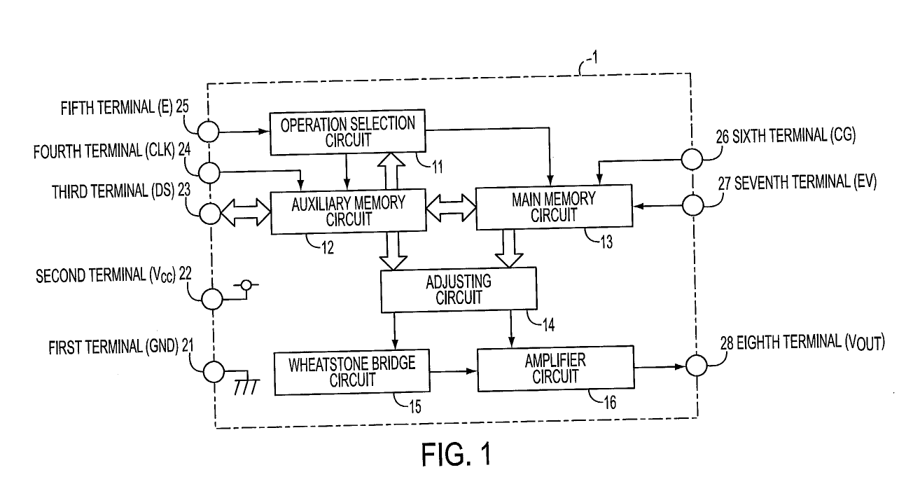

FIG. 1 is a block diagram showing one example of a semiconductor physical quantity sensing device according to an embodiment of the present invention. This semiconductor physical quantity sensing device 1 includes, for example, operation selection circuit 11, auxiliary memory circuit 12, main memory circuit 13, adjusting circuit 14, wheatstone bridge circuit 15 formed of sensor elements, amplifier circuit 16 and eight (first through eighth) terminals 21 to 28, respectively.

First terminal 21 supplies a ground potential to semiconductor physical quantity sensing device 1. Second terminal 22 supplies an operating voltage to semiconductor physical quantity sensing device 1. Third terminal 23 performs inputting/outputting of serial digital data (serial data). Fourth terminal 24 inputs an external clock. Fifth terminal 25 inputs a control signal to the internal digital circuit. Sixth terminal 26 supplies a voltage that is equal to or higher than the operating voltage applied to second terminal 22. Seventh terminal 27 supplies a voltage that is equal to or higher than the operating voltage applied to second terminal 22 and is different from the voltage applied to sixth terminal 26. Eighth terminal 28 outputs to the exterior a signal of semiconductor physical quantity sensing device 1.

Auxiliary memory circuit 12, according to an operation timing of the above-mentioned external clock, converts the serial digital data supplied from the exterior into parallel digital data (parallel data) that will be used internally. In addition, auxiliary memory circuit 12 converts the parallel digital data used internally into serial digital data for outputting to the exterior. Further, auxiliary memory circuit 12 also supplies control data to operation selection circuit 11. In accordance with the applied voltages of sixth terminal 26 and seventh terminal 27, main memory circuit 13 stores the trimming data which includes the parallel digital data supplied from auxiliary memory circuit 12.

Operation selection circuit 11, based on the control signal inputted into fifth terminal 25 and the control data supplied from auxiliary memory circuit 12, supplies a signal to control input/output of data, to auxiliary memory circuit 12 and main memory circuit 13. Wheatstone bridge circuit 15 generates an output signal responsive to a physical quantity of a medium being measured. Amplifier circuit 16 amplifies the output signal of wheatstone bridge circuit 15 and outputs that to the exterior via eighth terminal 28. Adjusting circuit 14, based on trimming data supplied from auxiliary memory circuit 12 or main memory circuit 13, performs sensitivity adjustments to wheatstone bridge circuit 15, taking into account temperature characteristics, and performs offset adjustments to amplifier circuit 16, again taking into account temperature characteristics.

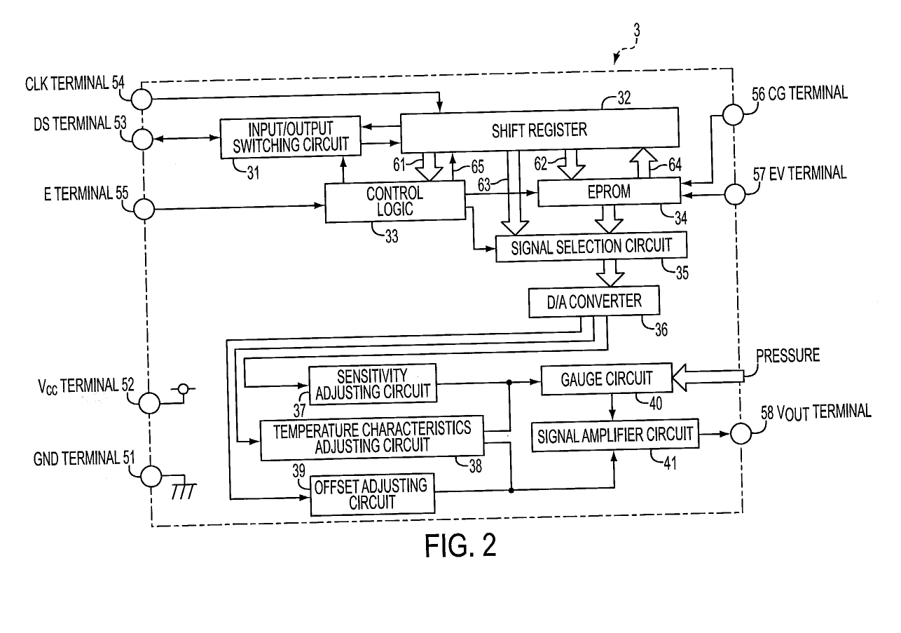

FIG. 2 is a block diagram showing one example of a semiconductor pressure-sensing device formed on a semiconductor chip according to an embodiment of the present invention. Semiconductor pressure-sensing device 3 comprises input/output switching circuit 31, shift register 32, control logic 33, EPROM 34, signal selection circuit 35, D/A converter 36, sensitivity adjusting circuit 37, temperature characteristics adjusting circuit (hereinafter, “TC adjusting circuit”) 38, offset adjusting circuit 39, gauge circuit 40 and signal amplifier circuit 41. Input/output switching circuit 31, shift register 32, control logic 33, EPROM 34, signal selection circuit 35, D/A converter 36, sensitivity adjusting circuit 37, TC adjusting circuit 38, offset adjusting circuit 39, gauge circuit 40 and signal amplifier circuit 41 are formed on the same semiconductor chip and are configured only from active and passive elements which are manufactured by means of a CMOS manufacturing process. In addition, for semiconductor pressure-sensing device 3 to receive power from the exterior and transfer signals to/from the exterior, GND terminal 51, Vcc terminal 52, DS terminal 53, CLK terminal 54, E terminal 55, CG terminal 56, EV terminal 57 and Vout terminal 58 are also provided.

GND terminal 51 and Vcc terminal 52 each supply to semiconductor pressure-sensing device 3 ground potential and power supply potential of, for example, and without particular limitation, 5V. DS terminal 53 is provided to send/receive serial digital data between semiconductor pressure-sensing device 3 and circuits external to it. CLK terminal 54 supplies an external clock to semiconductor pressure-sensing device 3. An “enable” signal is provided to E terminal 55 from the exterior, to control the operating state of the digital circuit(s) inside semiconductor pressure-sensing device 3. The Vout terminal 58 outputs the detection signal of semiconductor pressure-sensing device 3 to the exterior of the device.

When data is being written into EPROM 34, a voltage higher than that applied to Vcc 52, for example, and without particular limitation, 26V, is applied to CG terminal 56. In addition, when data is being written into EPROM 34, a voltage higher than the operating voltage applied to Vcc terminal 52 and also different from the voltage applied to CG terminal 56, for example, and without particular limitation, 13V, is applied to EV terminal 57. It may also be configured such that CG terminal 56 and EV terminal 57 are used jointly, that is, as the same terminal, so that based on the voltage applied to one terminal, the voltage applied to the other terminal is produced.

Input/output switching circuit 31 performs switching between a mode where trimming data, includes serial digital data supplied from the exterior via DS terminal 53, and is supplied to shift register 32 and the mode where serial digital data supplied from shift register 32 is supplied to the exterior via DS terminal 53. Shift register 32, synchronized to the above-mentioned external clock, converts serial digital data supplied from the exterior into parallel digital data. In addition, shift register 32 converts the trimming data, which includes parallel digital data stored 1 in EPROM 34, into serial digital data.

EPROM 34 stores trimming data including parallel digital data supplied from shift register 32. Signal selection circuit 35 selects either trimming data having parallel digital data supplied from shift register 32 or trimming data having parallel digital data supplied from EPROM 34, and supplies it to D/A converter 36. Control logic 33, based on an “enable” signal inputted from E terminal 55 and control data supplied from shift register 32, generates control signals and outputs them to input/output switching circuit 31, shift register 32, EPROM 34 and signal selection circuit 35 to control the operation of each of these. Here, to facilitate description, the control signal supplied to shift register 32 from control register 33 is designated as shift register control signal 65. D/A converter 36 converts trimming data having parallel digital data to analog data.

Gauge circuit 40 is configured from a semiconductor strain gauge, which, for example, generates an output signal responsive to applied pressure. Signal amplifier circuit 41 amplifies a signal generated by gauge circuit 40 and outputs it to the exterior via Vout terminal 58. Sensitivity adjusting circuit 37 trims a current applied to gauge circuit 40 according to the output of D/A converter 36. Similarly, offset adjusting circuit 39 trims a reference voltage used for adjusting the offset of signal amplifier circuit 41 according to the output of D/A converter 36. TC adjusting circuit 38 performs addition/subtraction to the outputs of sensitivity adjusting circuit 37 and offset adjusting circuit 39 according to the output of D/A converter 36.

Here, input/output switching circuit 31, shift register 32, control logic 33, EPROM 34, signal selection circuit 35, and D/A converter 36 correlate to a digital circuit portion. In contrast, sensitivity adjusting circuit 37, TC adjusting circuit 38, offset adjusting circuit 39, gauge circuit 40 and signal amplifier circuit 41 correlate to an analog circuit portion.

In the above-mentioned configuration, shift register 32 may perform the function of auxiliary memory circuit 12. EPROM 34 performs the function of main memory circuit 13. Input/output switching circuit 31, control logic 33, and signal selection circuit 35 may perform the function of operation selection circuit 11. D/A converter 36, sensitivity adjusting circuit 37, TC adjusting circuit 38 and offset adjusting circuit 39 may perform the function of adjusting circuit 14. Gauge circuit 40 may perform the function of wheatstone bridge 15. Signal amplifier circuit 41 may perform the function of amplifier circuit 16. In addition, GND terminal 51, Vcc terminal 52, DS terminal 53, CLK terminal 54, E terminal 55, CG terminal 56, EV terminal 57 and Vout terminal 58 would correspond, respectively, to the first through eighth terminals 21 to 28.

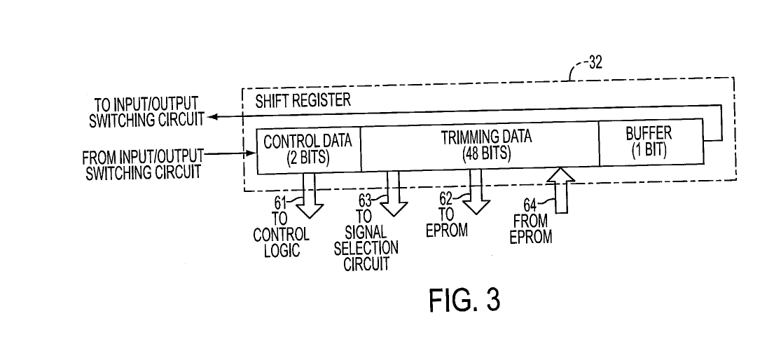

FIG. 3 is a diagram illustrating, in a simplified form, one example of a configuration for shift register 32. A bit count of shift register 32 may be, for example, and without particular limitation, 51 bits. Of those, two bits store control data 61, which is supplied to control logic 33. Following these two bits, 48 bits are used to store either data 62, which is supplied to EPROM 34, trimming data 63, which is supplied to signal selection circuit 35, or data 64, which is supplied from EPROM 34. The remaining one bit is used as a buffer.

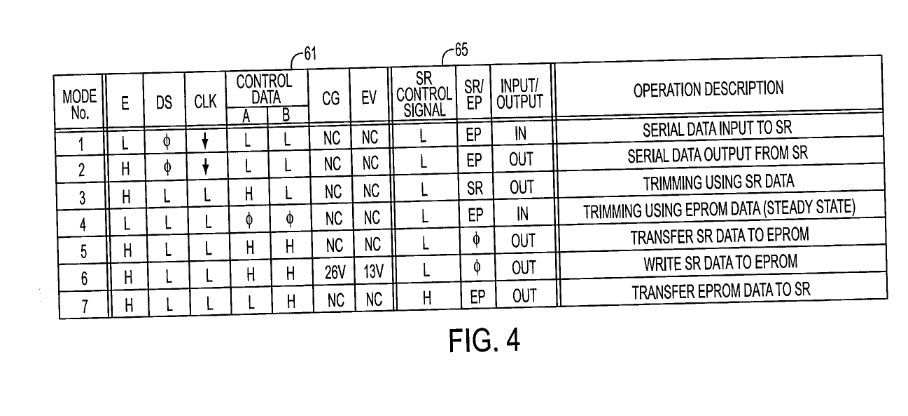

Next, while referring to FIG. 4, various control signals and a relationship between the applied voltages and the operating modes of semiconductor pressure-sensing device 3 will be described. When an external clock is inputted to CLK terminal 54, both CG terminal 56 and EV terminal 57 are in a “non-charged” state, E terminal 55 input is at a L level, and the 2 bits of control data 61 (A and B) are at the L level, upon inputting serial digital data to DS terminal 53, shift register (SR) control signal 65 then goes to the L level, signal selection circuit 35 selects EPROM 34, and input/output switching circuit 31 goes to “input.” As a result, serial digital data from the exterior is inputted into shift register 32 (Mode No. 1).

When an external clock is inputted to CLK terminal 54, both CG terminal 56 and EV terminal 57 are in the “non-charged” state, E terminal 55 input is at a H level, and the 2 bits of control data 61 (A and B) are at the L level, shift register control signal 65 then goes to the L level, signal selection circuit 35 selects EPROM 34, and input/output switching circuit 31 goes to “output.” As a result, serial digital data from shift register 32 is outputted to the exterior (Mode No. 2).

When E terminal 55 input is at the H level, DS terminal 53 input is at the L level, CLK terminal 54 input is at the L level, the first bit (A) and second bit (B) of control data 61 are respectively at the H level and the L level, and both CG terminal 56 and EV terminal 57 are in the “non-charged” state, then shift register control signal 65 goes to the L level, signal selection circuit 35 selects shift register 32, and input/output switching circuit 31 goes to “output.” As a result, trimming is performed using data stored in shift register 32 (Mode No. 3).

When E terminal 55 input is at the L level, DS terminal 53 input is at the L level, CLK terminal 54 input is at the L level, and both CG terminal 56 and EV terminal 57 are in the “non-charged” state, then shift register control signal 65 goes to the L level, signal selection circuit 35 selects EPROM 34, and input/output switching circuit 31 goes to “input.” As a result, the semiconductor pressure-sensing device goes into steady state, with trimming being performed using data stored in EPROM 34 (Mode No. 4).

When E terminal 55 input is at the H level, DS terminal 53 input is at the L level, CLK terminal 54 input is at the L level, the 2 bits (A and B) of control data 61 are at the H level, and both CG terminal 56 and EV terminal 57 are in the “non-charged” state, then shift register control signal 65 goes to the L level and input/output switching circuit 31 goes to “output.” As a result, data stored in shift register 32 is transferred to EPROM 34 (Mode No. 5).

When E terminal 55 input is at the H level, DS terminal 53 input is at the L level, CLK terminal 54 input is at the L level, the 2 bits (A and B) of control data 61 are at the H level, and both CG terminal 56 and EV terminal 57 are in a state where write voltages are applied, then shift register control signal 65 goes to the L level and input/output switching circuit 31 goes to “output.” As a result, data stored in shift register 32 is written into EPROM 34 (Mode No. 6).

When E terminal 55 input is at the H level, DS terminal 53 input is at the L level, CLK terminal 54 input is at the L level, the first bit (A) and second bit (B) of control data 61 are respectively at the L level and the H level, and both CG terminal 56 and EV terminal 57 are in the “non-charged” state, then shift register control signal 65 goes to the H level, signal selection circuit 35 selects EPROM 34, and input/output switching circuit 31 goes to “output.” As a result, data stored in EPROM 34 is transferred to shift register 32 (Mode No. 7).

Next, a procedure for performing trimming of semiconductor pressure-sensing device 3 is described. Each terminal of semiconductor pressure-sensing device 3 is set so that when a voltage, which is the operating power supply, for example 5V, is applied through Vcc terminal 52, the semiconductor pressure-sensing device automatically goes into the steady state of above-mentioned Mode No. 4. In an initial state where trimming has not been done, EPROM 34 is in an “all zero” state where nothing has been stored in memory. At this time, the signal amplifier circuit 41 and Vout terminal 58 are in a saturated state, that is, a state at or near either the power supply potential or the earth potential.

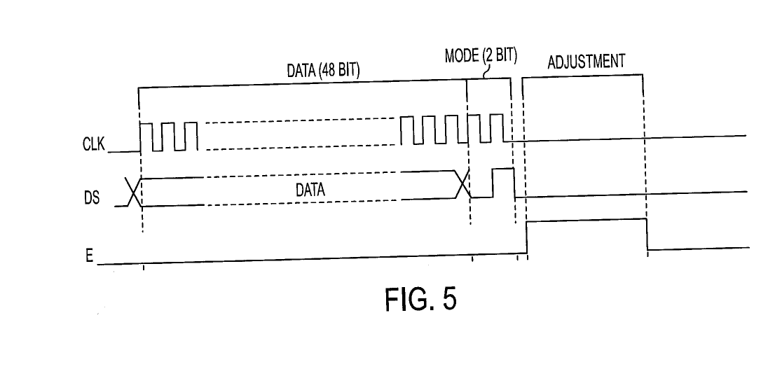

As illustrated in the timing chart of FIG. 5, by inputting trimming data from DS terminal 53, while inputting an external clock into CLK terminal 54, and by setting E terminal 55 to the L level, trimming data from the exterior is stored in shift register 32 (Mode No. 1). Then, by setting CLK terminal 54 and DS terminal 53 to the L level, and also setting E terminal 55 to the H level, trimming is done using trimming data stored in shift register 32 (Mode No. 3). At this time, sensor output from Vout terminal 58 is measured. This provisional trimming operation is repeated until the desired sensor output is obtained. In other words, by measuring sensor output while gradually changing the provisional trimming data inputted from outside, trimming data which results in the desired sensor output can be determined.

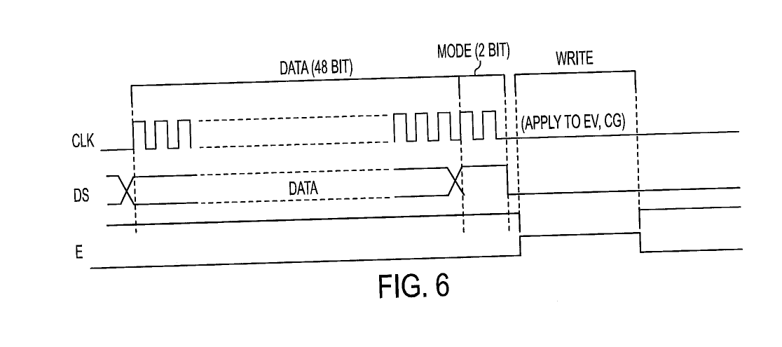

Once the trimming data has been determined, finalized trimming data from outside is stored in shift register 32 by inputting the finalized trimming data from DS terminal 53, while inputting an external clock into CLK terminal 54 and setting E terminal 55 to the L level, as in the timing chart shown in FIG. 6 (Mode No. 1). Next, setting E terminal 55 to the H level, DS terminal 53 to the L level and CLK terminal 54 to the L level, finalized trimming data is transferred from shift register 32 to EPROM 34 (Mode No. 5). Afterward, “write” voltages are applied to each of CG terminal 56 and EV terminal 57, and trimming data transferred from shift register 32 is written into EPROM 34 (Mode No. 6).

Upon completion of writing, the trimming operation is finished. Thereafter, semiconductor pressure sensor device 3 is used in its initial state (Mode No. 4). In this way, desired sensor characteristics can always be obtained, based on trimming data stored in EPROM 34.

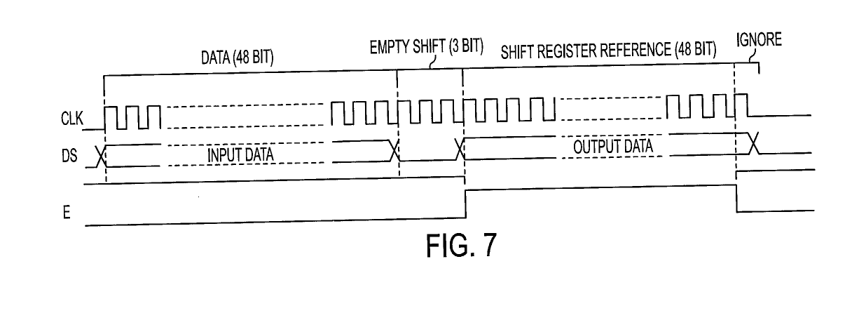

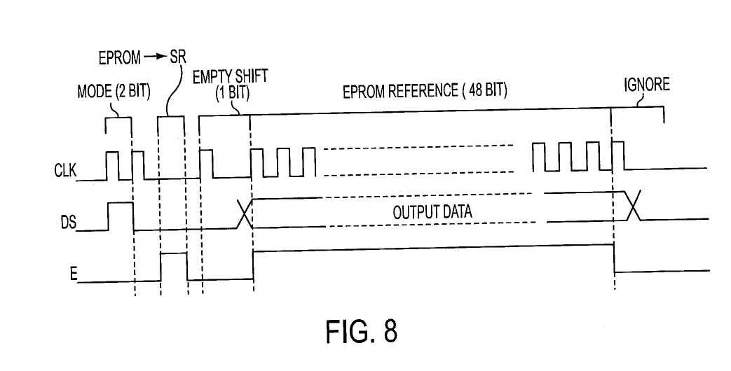

In addition, before starting a provisional trimming operation, by inputting provisional trimming data from DS terminal 53, while inputting an external clock into CLK terminal 54 and setting E terminal 55 to the L level, provisional trimming data from the exterior is stored in shift register 32, as illustrated in the timing chart of FIG. 7 (Mode No. 1). Thereafter, if E terminal 55 is set to the H level, the provisional trimming data stored in shift register 32 can be outputted from DS terminal 53 (Mode No. 2). This causes the provisional trimming data inputted from DS terminal 53 to be outputted to DS terminal 53 unchanged, after being routed through input/output switching circuit 31 and shift register 32. As a result, this provides a quality check on the operation of shift register 32 and input/output switching circuit 31. In other words, by executing the timing chart illustrated in FIG. 7, it is possible to perform a quality check on the operation of shift register 32 and input/output switching circuit 31. Furthermore, among the bits of the timing chart illustrated in FIG. 7, those designated “ignore” are bits that are not related to trimming adjustment and thus may be ignored. The same is true of FIG. 8 which is discussed later.

In addition, by setting E terminal 55 to the H level, DS terminal 53 to the L level, CLK terminal 54 to the L level, as illustrated in the timing chart of FIG. 8, trimming data stored in EPROM 34 can be transferred to shift register 32 (Mode No. 7). After transfer, if E terminal 55 is set to the H level while inputting an external clock to CLK terminal 54, the trimming data stored in shift register 32 can be outputted from DS terminal 53 (Mode No. 2). In this manner, trimming data stored in EPROM 34 can be outputted from DS terminal 53, thus making it possible to check EPROM 34 operation quality, examine EPROM 34 data holding capacity, and study sources of trouble with sensor characteristics after trimming. This is very effective for quality assurance and quality control of semiconductor pressure sensor devices 3.

According to the above-mentioned embodiments, by measuring sensor output while gradually changing the provisional trimming data stored in shift register 32, trimming data which results in the desired sensor output is determined and stored in EPROM 34, and in a normal operating state, sensor output is adjusted by sensitivity adjusting circuit 37, TC adjusting circuit 38 and offset adjusting circuit 39, using trimming data stored in EPROM 34. Because each of these configuration elements is formed only of active elements and passive elements manufactured by the CMOS manufacturing process and because, moreover, these elements together with the seven or eight terminals are formed on the same semiconductor chip, a semiconductor physical quantity sensing device is obtained which can perform electric trimming cheaply and with a small number of terminals.

The present invention, as described above, need not be limited to semiconductor pressure-sensing devices, but can be applied to sensing devices for a variety of physical quantities, such as temperature, humidity, speed, acceleration, light, magnetism or sound.

According to the present invention, the configuration is such that, by measuring sensor output while gradually changing the provisional trimming data stored in an auxiliary memory circuit, trimming data which results in the desired sensor output is determined and stored in a main memory circuit, and in a normal operating state, sensor output is adjusted by way of adjusting circuit(s), using trimming data stored in the main memory circuit. Because the sensor element, auxiliary memory circuit, main memory circuit and adjusting circuit(s) are formed only of active elements and passive elements manufactured by the CMOS manufacturing process and because, moreover, these elements together with the seven or eight terminals are formed on the same semiconductor chip, a semiconductor physical quantity sensing device is obtained which can perform electric trimming cheaply and with a small number of terminals.

Although only a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A semiconductor physical quantity sensing device, comprising:
a sensor element to generate an electric signal responsive to a detected physical quantity;
an output terminal to output to the exterior the electric signal generated by the sensor element;
a data input terminal to input serial digital data to be trimming data for adjusting an output characteristic of the sensor element;
an auxiliary memory circuit to temporarily store trimming data inputted from the data input terminal;
a re-writable read-only main memory circuit to store, by way of an electrical re-write action, the trimming data stored in said auxiliary memory circuit; and
an adjusting circuit to adjust the output characteristic of the sensor element based on trimming data stored in the auxiliary memory circuit or trimming data stored in the main memory circuit,
said operation of the semiconductor physical quantity sensing device being configured to include only active and passive elements formed on the same semiconductor chip and manufactured by a CMOS manufacturing process.

2. The semiconductor physical quantity sensing device of claim 1, wherein the auxiliary memory circuit converts inputted serial digital data to parallel digital data and supplies the converted data to circuits within the semiconductor physical quantity sensing device.

3. The semiconductor physical quantity sensing device of claim 1, having a sensitivity adjusting circuit to perform change/adjustment of current applied to the sensor element based on the trimming data to set a sensitivity of the sensor element.

4. The semiconductor physical quantity sensing device of claim 3, further comprising a temperature characteristics adjusting circuit to perform an addition/subtraction in respect to an output of said sensitivity adjusting circuit.

5. The semiconductor physical quantity sensing device of claim 2, having a sensitivity adjusting circuit to perform change/adjustment of current applied to the sensor element based on the trimming data to set a sensitivity of the sensor element.

6. The semiconductor physical quantity sensing device of claim 1, further comprising an amplifier circuit to amplify and output the electric signal generated by the sensor element, wherein the adjusting circuit further includes an offset adjusting circuit to change/adjust a reference voltage for offset adjustment of the amplifier circuit.

7. The semiconductor physical quantity sensing device of claim 6, wherein the adjusting circuit further includes a temperature characteristics adjusting circuit to perform addition/subtraction to an outputs of a sensitivity adjusting circuit and the offset adjusting circuit.

8. The semiconductor physical quantity sensing device of claim 2, further comprising an amplifier circuit to amplify and output the electric signal generated by the sensor element, wherein the adjusting circuit further includes an offset adjusting circuit to change/adjust a reference voltage for offset adjustment of the amplifier circuit.

9. The semiconductor physical quantity sensing device of claim 8, wherein the adjusting circuit further includes a temperature characteristics adjusting circuit to perform addition/subtraction to an outputs of a sensitivity adjusting circuit and the offset adjusting circuit.

10. The semiconductor physical quantity sensing device of claim 3, further comprising an amplifier circuit to amplify and output the electric signal generated by the sensor element, wherein the adjusting circuit further includes an offset adjusting circuit to change/adjust a reference voltage for offset adjustment of the amplifier circuit.

11. The semiconductor physical quantity sensing device of claim 10, wherein the adjusting circuit further includes a temperature characteristics adjusting circuit to perform addition/subtraction to an outputs of a sensitivity adjusting circuit and the offset adjusting circuit.

12. The semiconductor physical quantity sensing device according to any one of claims 1 through 11,
wherein the data input terminal also functions as a terminal to output data stored in the auxiliary memory circuit;
the auxiliary memory circuit outputs stored data as serial digital data; and
the semiconductor physical quantity sensing device sensing device further includes, between the data input terminal and the auxiliary memory circuit, an input/output switching circuit to switch between either supplying to the auxiliary memory circuit serial digital data inputted from the data input terminal or supplying to the data input terminal serial digital data outputted from the auxiliary memory circuit.

13. The semiconductor physical quantity sensing device according to any one of claims 1 through 11, having seven terminals in total, including the output terminal, the data input terminal, a terminal to supply earth potential, a terminal to supply operating voltage, a terminal to input an external clock, a terminal to input signals to control internal digital circuits, and a terminal to supply a write voltage higher than an operating voltage for writing data into the main memory circuit, and also including a circuit to generate a different second write voltage based on the write voltage.

14. The semiconductor physical quantity sensing device according to any one of claims 1 through 11, having eight terminals in total, including the output terminal, the data input terminal, a terminal to supply earth potential, a terminal to supply operating voltage, a terminal to input an external clock, a terminal to input signals to control internal digital circuits, a terminal to supply first write voltage higher than an operating voltage to write data into the main memory circuit, and a terminal to supply a second write voltage higher than the operating voltage and different from the first write voltage.
